(19) United States
(12) Patent Application Publication
(10) Pub. No.: US 2006/0181929 A1
(43) Pub. Date: Aug. 17, 2006

(54) Semiconductor memory device

(75) Inventors: Hideto Kotani, Takatsuki-shi (JP); Satoshi Mishima, Kobe-shi (JP); Masahiro Toki, Otsu-shi (JP); Hoshihide Haruyama, Kyoto-shi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/354,066

(22) Filed: Feb. 15, 2006

(30) Foreign Application Priority Data
Feb. 15, 2005 (JP) P2005-037607

(51) Int. Cl. G11C 11/34

(52) U.S. Cl. 365/185.22

(57) ABSTRACT

To implement a high reliability and large number of rewrite operations by optimizing reliability margins of both data “0” and data “1” or a reliability margin of one of the data “0” or data “1” with a circuit for monitoring a rewrite status and a circuit for changing a read condition corresponding to the number of rewrite operations based on a result of monitoring the rewritable status.

### BACKGROUND OF THE INVENTION

1. Field of the Invention

The present invention relates to a semiconductor memory device and more specifically, to a semiconductor memory device including an electrically rewritable nonvolatile semiconductor memory having a unit which changes a read condition so as to optimize to the number of rewrite operations by a result of monitoring a rewrite status.

2. Description of the Related Art

In recent years, most of apparatuses which are capable of being connected to a network, such as a cellular phone and a home appliance, have intelligent functions on the basis of a ubiquitous computing environment. Under this situation, it has been highly requested to move from the age of turning on a computer, loading a program from a hard disk to a main memory, and performing a corresponding application to the age of simultaneously driving an application while turning on a computer.

An SRAM, a DRAM, and a flash memory have been used as a standard of a read and write memory. The SRAM is unsuitable for a large capacity memory because it is difficult to make the SRAM be integrated at a large scale. However the SRAM has been used for a cache memory with a high clock speed. The DRAM has a slow access speed due to a refresh operation but the DRAM has large capacity memory and is used for a computer main memory and so on. Since the flash memory is nonvolatile (it does not need to be electrically stored) like the hard disk, the flash memory has been used for relatively small data storage.

At present, a universal memory is requested to surpass the above-described compartmentalization of each memory and combine each of the advantages of the SRAM, the DRAM, and the flash memory.

Conditions required for the universal memory are as follows.

high-speed access of SRAM level (write/read)

large-scale integration of DRAM level (high capacity)

nonvolatile memory like the flash memory

low power consumption that is capable of being driven by a small size battery

A next generation nonvolatile memory called the universal memory may include an MRAM (magnetic RAM), a FeRAM (ferroelectric RAM), and an OUM (ovonics unified memory). If the next generation nonvolatile memories are implemented, it is possible to create an environment capable of performing an application just by turning on a computer as well as using a small and high-functional cellular phone or various kinds of home appliances.

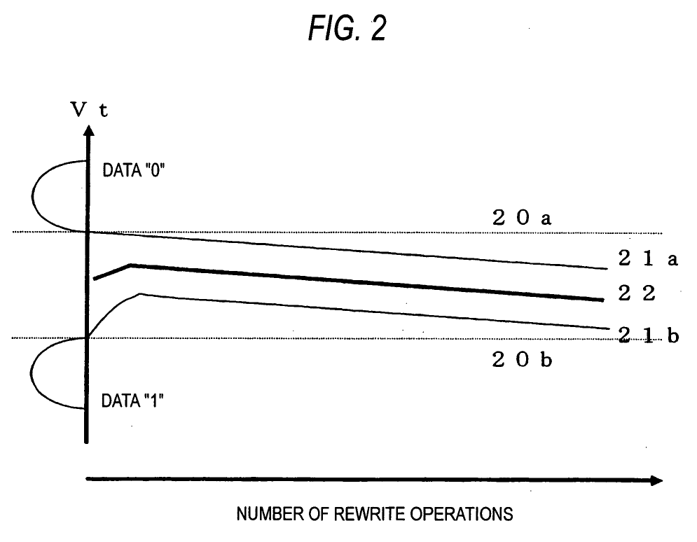

In creating this kind of next generation model, for example, an associative memory which stores data in a plurality of memory regions, the retrieving data is inputted from an external and retrieves addresses within the memory regions in which the data corresponding to input retrieving data is stored is proposed (JP-A-2001-23384 (FIG. 2)). In such an associative memory, a basic operation such as read, write, or delete operation should be effectively repeated at a high-speed without malfunctioning. For this reason, the design of an operation range is very important when designing a memory.

In an electrically rewritable nonvolatile memory such as a flash memory according to the related art, when designing the operation region, the threshold level of a memory cell is designed so as to be an optimum operating point by acquiring a reliability margin and a circuit margin needed for each of data “0” and data “1” based on the concept of fixed read, write, and delete levels. Here, the reliability margin is needed with respect to reliability merit which is deterioration of a threshold voltage at the guaranteed worst cycling numbers/temperature. Here, the reliability merit is a merit value (degree) of the reliability of a corresponding circuit.

However, when acquiring a predetermined amount of reliability margin, this kind of memory should acquire a writing or deleting margin by considering the worst condition.

There is no problem when the reliability of a memory cell in a nonvolatile semiconductor memory has the worst condition in both writing and deleting at the same cycle numbers. However, when the reliability merit of the memory cell in a nonvolatile semiconductor memory has the worst condition at cycle numbers different from in writing or deleting sides, there is a problem in that a cycle window becomes bigger and an excess merit is requested in the device because the worst condition should be considered when acquiring margins of writing/deleting sides.

### SUMMARY OF THE INVENTION

The present invention is made in consideration of the above-described problem, and it is an advantage of the invention that it provides an electrically rewritable nonvolatile semiconductor memory having high reliability and a large number of rewrite operations.

In order to achieve the above-mentioned advantage, the electrically rewritable nonvolatile semiconductor memory according to the invention includes a circuit for monitoring a rewrite status and a circuit for changing a read condition corresponding to the number of rewrite operations.

According to above-described configuration, it is possible to optimize reliability margins of both data “0” and data “1” or a reliability margin of one of the data “0” or data “1”. In addition, it is possible to implement an electrically rewritable nonvolatile semiconductor memory with a high reliability and large number of rewrite operations.

An electrically rewritable semiconductor memory device according to the invention includes: a rewritable nonvolatile semiconductor memory; a measuring unit which measures a threshold voltage of data after the nonvolatile semiconductor memory is rewritten; and an adjustment unit which adjusts a read condition so as to correspond to the number of rewrite operations on the basis of a measurement result of a rewrite status acquired by the measuring unit.

In accordance with this configuration, since a read condition is set by considering a rewrite status, it is possible to provide an excellent nonvolatile semiconductor memory without unnecessary large margin.

In addition, the electrically rewritable semiconductor memory device according to the invention further includes a counter circuit which counts the number of rewrite operations of the nonvolatile semiconductor memory and monitors a threshold voltage acquired from the measuring unit in correspondence with the number of rewrite operations counted by the counter circuit.

In accordance with this configuration, it is possible to simply monitor the rewrite status by monitoring depending on the number of rewrite operations.

In addition, the electrically rewritable semiconductor memory device according to the invention acquires the rewrite status by monitoring a rewrite property of the nonvolatile semiconductor memory.

In accordance with this configuration, it is possible to more simply monitor the rewrite status.

In addition, the electrically rewritable semiconductor memory device according to the invention, acquires the rewrite status by monitoring a data storage property of the nonvolatile semiconductor memory.

In addition, the electrically rewritable semiconductor memory device according to the invention further includes an electrically rewritable nonvolatile semiconductor memory for referring to the number of rewrite operations in an additional region. The electrically rewritable nonvolatile semiconductor memory for referring to the number of rewrite operations is rewritten while a data region is rewritten.

In addition, the electrically rewritable semiconductor memory device according to the invention acquires the rewrite status by monitoring a data storage property of a nonvolatile semiconductor memory just before the data region is read.

In addition, the electrically rewritable semiconductor memory device according to the invention acquires the rewrite status by monitoring a data storage property when a predetermined time is passed after a nonvolatile semiconductor memory is rewritten.

In addition, the electrically rewritable semiconductor memory device according to the invention acquires the data storage property by monitoring the data storage property with respect to both data “0” and data “1”.

In accordance with this configuration, it is possible to acquire further high precision data storage property and provide a semiconductor memory device having high reliability.

In addition, the electrically rewritable semiconductor memory device according to the invention monitors the data storage property with respect to one of data “0” and data “1” which has a data storage property stronger than the other.

In accordance with this configuration, it is possible to simply process data by monitoring only strong data.

In addition, the electrically rewritable semiconductor memory device according to the invention monitors the data storage property with respect to one of data “0” and data “1” which has a data storage property no stronger than the other.

In accordance with this configuration, it is possible to simply process data without decreasing the reliability by monitoring with respect to only the data storage property which is not strong and considering the data storage property only when exceeding a predetermined threshold while the data storage property is not considered commonly.

In addition, the electrically rewritable semiconductor memory device according to the invention reflects a data storage property to the read condition during a test.

In addition, the electrically rewritable semiconductor memory device according to the invention stores a rewrite property during a test in a chip, and reflects the difference of a rewrite property stored in the chip to the read condition when performing a rewrite operation in the nonvolatile semiconductor memory.

In addition, in the electrically rewritable semiconductor memory device according to the invention, the nonvolatile semiconductor memory may be a flash memory.

In addition, in the electrically rewritable semiconductor memory device according to the invention, the nonvolatile semiconductor memory may be a ferroelectric memory (FeRAM).

According to the above aspects of the invention, it is possible to implement an electrically rewritable nonvolatile semiconductor memory, which can optimize a reliability margin needed for a device in a direction of the number of rewrite operations and has high-reliability and large number of rewrite operations, by changing a level when reading data.

### BRIEF DESCRIPTION OF DRAIWNGS

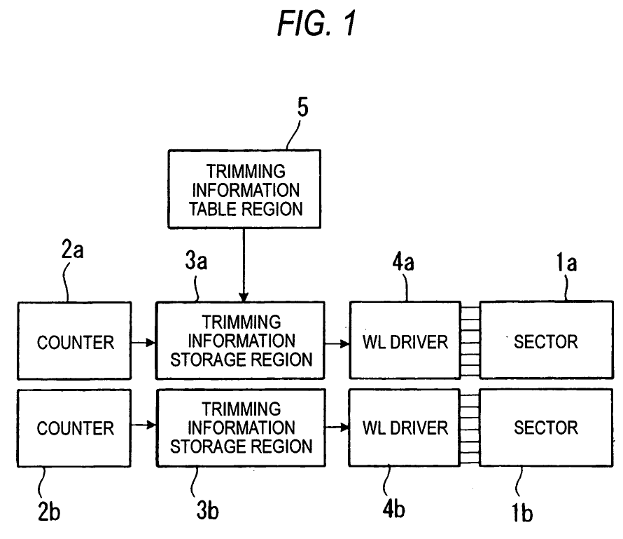

FIG. 1 is a block diagram showing an electrically rewritable nonvolatile semiconductor memory according to a first embodiment.

FIG. 2 is a view showing a method of setting a gate voltage of the electrically rewritable nonvolatile semiconductor memory according to a second embodiment.

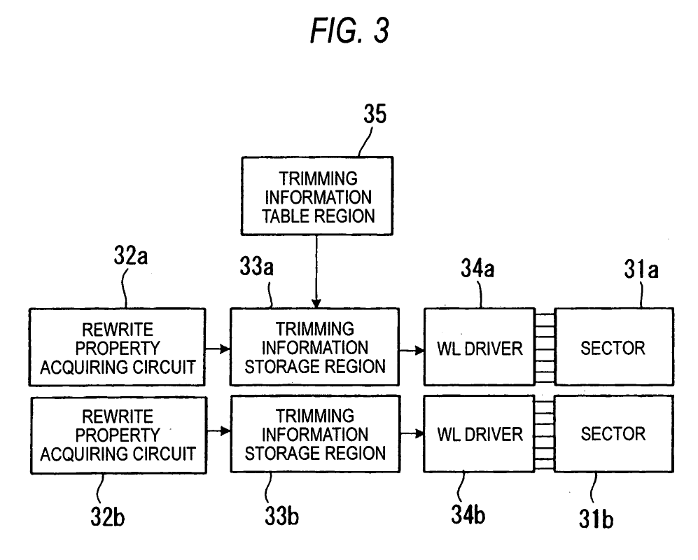

FIG. 3 is a block diagram showing an electrically rewritable nonvolatile semiconductor memory according to a third and a fourth embodiments.

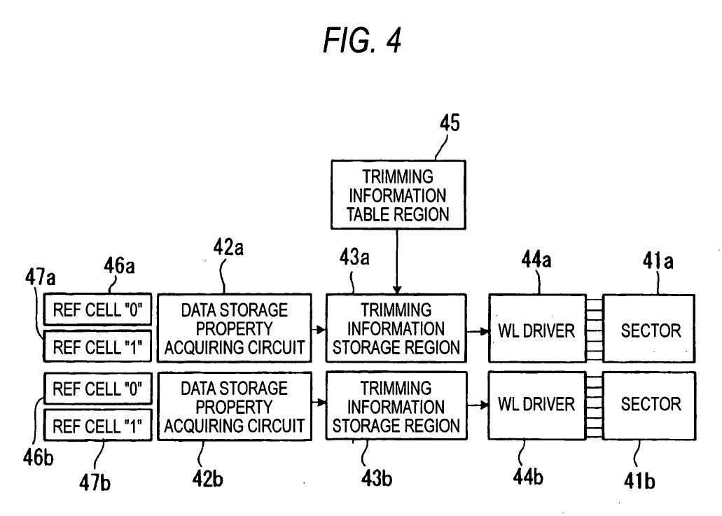

FIG. 4 is a block diagram showing an electrically rewritable nonvolatile semiconductor memory according to a fifth and a sixth embodiments.

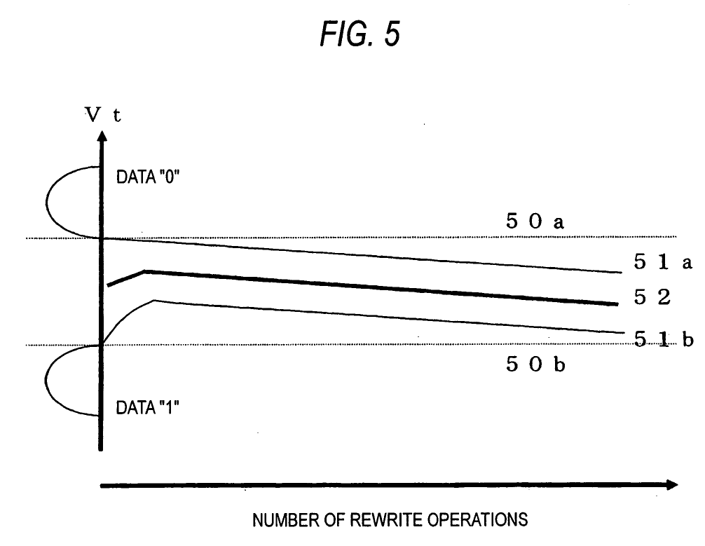

FIG. 5 is a view showing a method of setting an optimal gate voltage for both data.

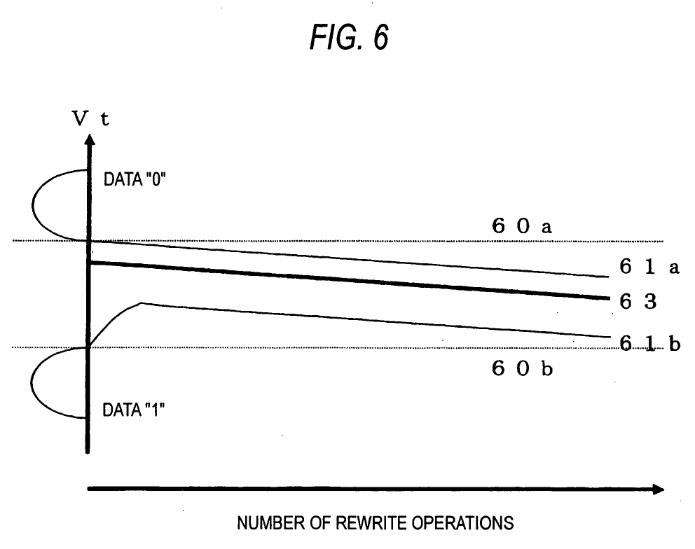

FIG. 6 is a view showing a method of setting an optimal gate voltage along to data “0”.

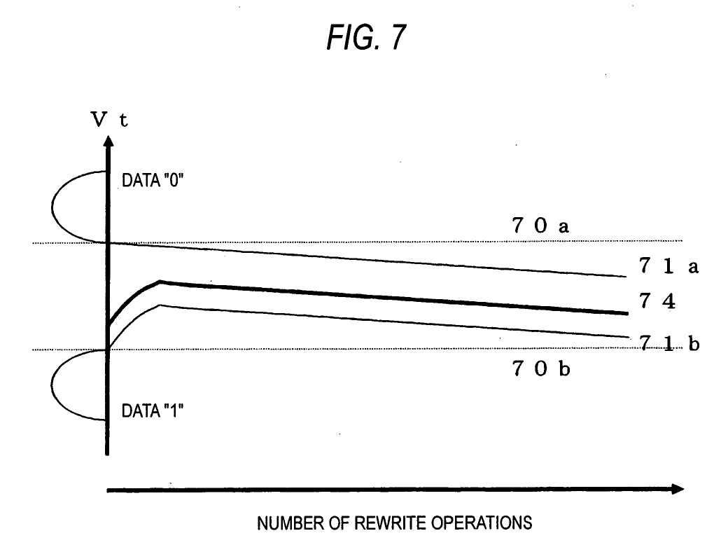

FIG. 7 is a view showing a method of setting an optimal gate voltage along to data “1”.

### DESCRIPTION OF THE PREFERRED EMBODIMENTS

Hereinafter, a first embodiment according to the present invention will be described with reference to drawings.

FIG. 1 is a block diagram showing a configuration of an electrically rewritable nonvolatile semiconductor memory according to the first embodiment. As a configuration shown in FIG. 1, the nonvolatile semiconductor memory includes memory cell array sectors 1a and 1b of the electrically rewritable nonvolatile semiconductor memory, counter circuits 2a and 2b which count the number of rewrite operations for every sector, trimming information storage regions 3a and 3b which store trimming information for adjusting a threshold voltage when performing a write or read operation in the memory cell array sectors 1a and 1b, word line (WL) drivers 4a and 4b serving as driving units which drive the memory cell array sectors 1a and 1b, and a trimming information table region 5 which determines the threshold voltage as trimming information based on measurement data measured in advance and stores it. The nonvolatile semiconductor memory rewrites the threshold voltage based on the number of rewrite operations. Here, the trimming information storage regions 3a and 3b may include an electrically rewritable nonvolatile semiconductor memory.

Hereinafter, an operation of the electrically rewritable nonvolatile semiconductor memory having the above-described configuration according to the first embodiment will be described.

First, a rewrite operation of the memory cell array sector 1a of the electrically rewritable nonvolatile semiconductor memory will be described. After the memory cell array sector 1a of the electrically rewritable nonvolatile semiconductor memory is rewritten, the number of rewrite operations are increased and stored in the counter circuit 2a. And then, the trimming information, which sets a gate voltage of the memory cell array sector 1a of the electrically rewritable nonvolatile semiconductor memory, which is supplied from the counter circuit 2a and the trimming information table region 5, to an optimal gate voltage depending on the number of rewrite operations, is stored in the trimming information storage region 3a. Accordingly, the rewrite operation of the memory cell array sector 1a of the electrically rewritable nonvolatile semiconductor memory is terminated.

Next, a read operation of the memory cell array sector 1a of the electrically rewritable nonvolatile semiconductor memory will be described.

The gate voltage acquired when reading the memory cell array sector 1a of the electrically rewritable nonvolatile semiconductor memory from the information stored in the trimming information storage region 3a is set as an optimal gate voltage depending on the number of rewrite operations to be provided to the memory cell array sector 1a of the electrically rewritable nonvolatile semiconductor memory by the WL driver 4a. And then, the read operation of the memory cell array sector 1a of the electrically rewritable nonvolatile semiconductor memory is performed.

As shown in FIG. 2, the optimal gate voltage depending on the number of rewrite operations is set to be an intermediate value 22 with respect to a reliability margin of a line 21b of data “1” and a line 21a of data “0” in the direction of the number of rewrite operations direction. Accordingly, it is possible to obtain better optimal reliability margin for the line 21b of data “1” and the line 21a of data “0” as compared with a method according to a related art. In addition, it is possible to increase the number of rewrite operations by using the increment of the reliability margin.

In addition, a rewrite or read operation of the memory cell array sector 1b of the electrically rewritable nonvolatile semiconductor memory is performed in the unit of sectors as the same as the above-described operation.

According to above-described embodiment, by providing the optimal gate voltage depending on the number of rewrite operations, it is possible to optimize the reliability margin, and to further increase the reliability or the number of rewrite operations with respect to a memory cell of the nonvolatile semiconductor memory as compared with the method according to the related art.

Next, a second embodiment according to the invention will be described.

Based on the data storage property during the test in the first embodiment, an electrically rewritable nonvolatile semiconductor memory according to the second embodiment directly rewrites contents stored in the trimming information table region 5 which are most suitable for a chip during the test and reflects the rewritten contents.

Since the data storage property varies according to the chips, the variation in the chips can be removed by changing the trimming information table region 5 depending on the data storage property during the test. Accordingly, lt is possible to increase the precision and reduce excessive margins.

According to the above-described embodiment, it is possible to remove the inconsistency in the reliability for every chip and to increase the reliability margin by reflecting the data storage property during the test into the trimming information table region 5.

Next, a third embodiment according to the invention will be described with reference to FIG. 3.

FIG. 3 is a block diagram showing a configuration of an electrically rewritable nonvolatile semiconductor memory according to the third embodiment. The nonvolatile semiconductor memory includes a rewrite property acquiring circuits 32a and 32b instead of the counters 2a and 2b described in the first embodiment. In FIG. 3, reference numerals 31a and 31b indicate memory cell sectors of the electrically rewritable nonvolatile semiconductor memory, reference numerals 32a and 32b indicate rewrite property acquiring circuits, reference numerals 33a and 33b indicates trimming information storage regions, reference numerals 34a and 34b indicates WL drivers, and reference numerals 35 indicates a trimming information table region. In this case, the trimming information storage regions 33a and 33b may be also configured by the electrically rewritable nonvolatile semiconductor memory.

Hereinafter, operations of the electrically rewritable nonvolatile semiconductor memory having the above-described configuration according to the third embodiment will be described.

First, a rewrite operation of the memory cell array sector 31a of the electrically rewritable nonvolatile semiconductor memory will be described. After the memory cell array sector 31a of the electrically rewritable nonvolatile semiconductor memory is rewritten, the rewrite property acquiring circuit 32a acquires a rewrite property of the memory cell array sector 31a of the electrically rewritable nonvolatile semiconductor memory. And then, trimming information, which sets a gate voltage of the memory cell array sector 31a of the electrically rewritable nonvolatile semiconductor memory to an optimal gate voltage depending on the number of rewrite operations, is stored from the rewrite property acquiring circuit 32a and the trimming information table region 35 to the trimming information storage region 33a. And then, the operation of the memory cell array sector 31a of the electrically rewritable nonvolatile semiconductor memory is terminated.

Next, a read operation of the memory cell array sector 31a of the electrically rewritable nonvolatile semiconductor memory will be described. On the basis of information of the trimming information storage region 33a, a gate voltage acquired when reading the memory cell array sector 31a of the electrically rewritable nonvolatile semiconductor memory is set to an optimal gate voltage depending on the number of rewrite operations and supplied to the memory cell array sector 31a of the electrically rewritable nonvolatile semiconductor memory by the WL driver 34a. Accordingly, the read operation of the memory cell array sector 31a of the electrically rewritable nonvolatile semiconductor memory is performed.

In addition, a rewrite or read operation of the memory cell array sector 31b of the electrically rewritable nonvolatile semiconductor memory is performed in the unit of sectors as described above.

If there is strong relationship between rewrite property and reliability, the margin can be further increased by reflecting the rewrite property of a device than reflecting the number of rewrite operations using a counter circuit.

As described above, it is possible to further increase the reliability margin as compared with a method according to the related art by setting the optimal gate voltage depending on the rewrite property. In addition, it is also possible to increase the reliability merit and the number of rewrite operations with respect to a memory cell of the electrically rewritable nonvolatile semiconductor memory.

Next, a fourth embodiment according to the invention will be described with reference to FIG. 3.

Based on the rewrite property during the test in the third embodiment, the electrically rewritable nonvolatile semiconductor memory according to the fourth embodiment directly rewrites contents of the trimming information table region 35 which is optimal to a corresponding chip and reflects the rewritten contents.

If there is strong relationship between rewrite property and reliability, there may be a case that the relationship between the difference of the rewrite property and a property in an initial state and the reliability becomes further stronger depending on the memory. In this case, it is possible to apply an optimal gate voltage depending on the rewrite property based on the relationship between the difference of the rewrite property and the property in the initial state and the reliability by reflecting the rewrite property during the test to the trimming information table region 35. In addition, it is also possible to remove the chip variation.

According to above-described embodiment, it is possible to remove the inconsistency in the reliability for every chip and further increase the reliability margin by reflecting the rewrite property during the search to the trimming information table region 35.

Next, a fifth embodiment according to the invention will be described with reference to FIG. 4.

FIG. 4 is a view showing a configuration of an electrically rewritable nonvolatile semiconductor memory according to the fifth embodiment. The nonvolatile semiconductor memory includes data storage property acquiring circuits 42a and 42b instead of the counters 2a and 2b described in the first embodiment. Here, the data storage property acquiring circuits 42a and 42b has memory cells 47a and 47b of a semiconductor memory device for data storage reference for data “1” and memory cells 46a and 46b of a semiconductor memory device for data storage reference for data “0”. In FIG. 4, reference numerals 41a and 41b indicate memory cell array sectors of the electrically rewritable nonvolatile semiconductor memory, reference numerals 42a and 42b indicate data storage property acquiring circuits, reference numerals 43a and 43b indicate trimming information storage regions, reference numerals 44a and 44b indicate WL drivers, reference numerals 45a indicates trimming information table region, reference numerals 46a and 46b indicate memory cells of semiconductor memory device for data storage reference for data “0”, and reference numerals 47a and 47b indicate memory cells of semiconductor memory device for data storage reference for data “1”. In this case, the memory cells 46a and 46b of semiconductor memory device for data storage reference for data “0” and the memory cells 47a and 47b of semiconductor memory device for data storage reference for data “1” may be configured by an electrically rewritable nonvolatile semiconductor memory.

The operation of the electrically rewritable nonvolatile semiconductor memory according to the fifth embodiment having the above-described configuration will be described.

First, a rewrite operation of the memory cell array sector 41a of the electrically rewritable nonvolatile semiconductor memory will be described. After the memory cell array sector 41a of the electrically rewritable nonvolatile semiconductor memory is rewritten, the memory cell 46a of the semiconductor memory device for data storage reference for the data “0” is rewritten as data “0” and the memory cell 47a of the semiconductor memory device for data storage reference for the data “1” is rewritten as data “1”. And then the rewrite operation is terminated.

Next, a read operation of the memory cell array sector 41a of the electrically rewritable nonvolatile semiconductor memory will be described. First, thresholds of the memory cell 46a of semiconductor memory device for data storage reference for data “0”, and the memory cell 47a of semiconductor memory device for data storage reference for data “1” are measured (hereinafter, referred to as Vt search). And then, the data storage property acquiring circuit 42a acquires data storage property of the data “0” and the data “1” after the rewrite operation is performed and just before the read operation is performed. Consequently, trimming information, which sets a gate voltage of the memory cell array sector 41a of the electrically rewritable nonvolatile semiconductor memory from the data storage property acquiring circuit 42a and the trimming information table region 45 to the optimal gate voltage depending on the number of rewrite operations, is stored in the trimming information storage region 43a. Accordingly, when reading the memory cell array sector 41a of the electrically rewritable nonvolatile semiconductor memory, the gate voltage is set to the optimal gate voltage depending on the number of rewrite operations and supplied to the memory cell array sector 41a of the electrically rewritable nonvolatile semiconductor memory by the WL driver 44a. Accordingly, the read operation of the memory cell array sector 41a of the electrically rewritable nonvolatile semiconductor memory is performed.

In addition, a rewrite and read operation of the memory cell array sector 41b of the electrically rewritable nonvolatile semiconductor memory is also performed in the unit of sectors as the same as the above-described read operation.

Since the data storage property can be reflected to the gate voltage when reading the memory cell array sector 41a of the electrically rewritable nonvolatile semiconductor memory until the read operation is performed, it is possible to improve a degree of precision when monitoring data.

According to above-described embodiment, the degree of precision when monitoring data is improved by setting the optimal gate voltage depending on data hold property just before the read operation. In addition, it is also possible to increase the reliability margin as compared with that in the related art, and further increase the reliability merit and the number of rewrite operations with respect to a memory cell of the electrically rewritable nonvolatile semiconductor memory.

The invention can be implemented without providing the memory cell 46a of the semiconductor memory device for data storage reference for the data “0” and the memory cell 47a of the semiconductor memory device for data storage reference for the data “1” separately from the memory cell array sector 41a of the electrically rewritable nonvolatile semiconductor memory.

Next, a sixth embodiment according to the invention will be described with reference to FIG. 4.

An electrically rewritable nonvolatile semiconductor memory according to the sixth embodiment performs acquirement of data storage properties of the data “0” and the data “1” of the fifth embodiment by performing a rewrite operation of the memory cell array sector 41a of the electrically rewritable nonvolatile semiconductor memory.

An operation of the electrically rewritable nonvolatile semiconductor memory according to the sixth embodiment will be described.

The memory cell 46a of the semiconductor memory device for data storage reference for the data “0” is rewritten to data “0”, the memory cell 47a of the semiconductor memory device for data storage reference for the data “1” is rewritten to data “1”, and the threshold search (Vt search) of the memory cell 46a of the semiconductor memory device for data storage reference for the data “0” and the memory cell 47a of the semiconductor memory device for data storage reference for the data “1” are performed. Accordingly, the threshold is acquired before the rewrite operation is performed.

The rewrite operation of the memory cell array sector 41a of the electrically rewritable nonvolatile semiconductor memory is performed again and the Vt search of the memory cell 46a of the semiconductor memory device for data storage reference for the data “0” and the memory cell 47a of the semiconductor memory device for data storage reference for the data “1” is performed again. Accordingly, the threshold after the rewrite operation is performed is acquired. Data storage properties of the data “0” and the data “1” which are being rewritten in the memory cell array sector 41a of the electrically rewritable nonvolatile semiconductor memory are acquired by the data storage property acquiring circuit 42a of the memory cells 46a and 47a of the semiconductor memory device for data storage reference. Accordingly, the difference between the threshold before the rewrite operation is performed and the threshold after the rewrite operation is performed is acquired.

And then, trimming information, which sets a gate voltage of the memory cell array sector 41a of the electrically rewritable nonvolatile semiconductor memory supplied from the data storage property acquiring circuit 42a and the trimming information table region 45 to the optimal gate voltage depending on the number of rewrite operations, is stored in the trimming information storage region 33a. Accordingly, the gate voltage during read when reading the memory cell array sector 31a of the electrically rewritable nonvolatile semiconductor memory is set to the optimal gate voltage depending on the number of rewrite operations and supplied to the memory cell array sector 31a of the electrically rewritable nonvolatile semiconductor memory by the WL driver 34a. Accordingly, the read operation of the memory cell array sector 31a of the electrically rewritable nonvolatile semiconductor memory is performed.

Since the gate voltage is determined on the basis of the data storage property when the rewrite operation is performed, the data storage property can be reflected to the gate voltage when reading the memory cell array sector of the electrically rewritable nonvolatile semiconductor memory without generating an overhead time, for example, for referring to the memory cell of the semiconductor memory device for data storage reference before the read operation is performed. In addition, it is also possible to increase the reliability margin and further increase the reliability merit and the number of rewrite operations with respect to a memory cell of the electrically rewritable nonvolatile semiconductor memory.

With reference to FIGS. 5 to 7, reference data and a gate voltage to be set will be described. FIGS. 5 to 7 are views showing changes of the data and the number of rewrite operations. Reference numeral 50a indicates a verifying level of data “0”, reference numeral 50b indicates a verifying level of data “1”, reference numeral 51a indicates data storage property in accordance with the number of rewrite operations of the data “0”, reference numeral 51b indicates data storage property in accordance with the number of rewrite operations of the data “1”, and reference numerals 52 to 54 indicate gate voltages to be set.

As shown in FIG. 5, in the fifth and sixth embodiments, it is possible to set a proper margin and an optimal gate voltage 52 with respect to data “0” and data “1” by allowing a memory cell of a semiconductor memory device for data storage reference to have both property 51a of the data “0” and property 51b of the data “1”.

In addition, when one of the data storage properties between the data “0” and the data “1” is mainly changed in accordance with the number of rewrite operations, the data to be monitored will be one of the data “0” or the data “1”. Accordingly, according to the embodiments of the invention, the operating time can be reduced by half the time of monitoring both data.

In an example shown in FIG. 6, it is possible to set a desired margin according to a change of the mainly changed data and set an optimal gate voltage 63 for half the time of monitoring the both data by monitoring only the property 61a of data “0” that is more mainly changed in accordance with the number of rewrite operations,

In contrast, in an example shown in FIG. 7, it is possible to set a desired margin according to a change of the data “1” and set an optimal gate voltage 74 by monitoring only the property 71b of data “1” which is not the mainly changed data, in accordance with the number of rewrite operations. At this time, it is possible to increase the margin and further improve the reliability with respect to the data storage property which is largely affected by the number of rewrite operations. Accordingly, it is possible to increase the reliability and the number of rewrite operations for half the time of monitoring both data.

The electrically rewritable nonvolatile semiconductor memory according to the invention includes a circuit for monitoring a rewrite status and a circuit for changing a read condition corresponding to the number of rewrite operations based on a monitor result of the rewritable status. With this configuration, the electrically rewritable nonvolatile semiconductor memory can optimize the reliability margin of both data “0” and data “1” or the reliability margin of one of the data “0” or data “1”. In addition, it is possible to implement an electrically rewritable nonvolatile semiconductor memory including a high reliability merit and large number of rewrite operations.

A semiconductor memory device according to the invention can optimize a reliability margin needed to a device in a direction of the number of rewrite operations by changing a level when reading data with the number of rewrite operations and has a high reliability and high number of rewrite operations. Further, the invention may implement a semiconductor memory device including an electrically rewritable nonvolatile semiconductor memory and may be applied to a MRAM, a FeRAM, an OUM as well as a flash memory.

What is claimed is:

1. An electrically rewritable semiconductor memory device, comprising:
a rewritable nonvolatile semiconductor memory;
a measuring unit, measuring a threshold voltage of data after the nonvolatile semiconductor memory is rewritten; and
an adjustment unit, adjusting a read condition so as to correspond to the number of rewrite operations on the basis of a measurement result of a rewrite status acquired by the measuring unit.

2. The electrically rewritable semiconductor memory device according to claim 1, further comprising:
a counter circuit, counting the number of rewrite operations of the nonvolatile semiconductor memory;
wherein a threshold voltage acquired from the measuring unit is monitored in correspondence with the number of rewrite operations counted by the counter circuit.

3. The electrically rewritable semiconductor memory device according to claim 1,
wherein the rewrite status is acquired by monitoring a rewrite property of the nonvolatile semiconductor memory.

4. The electrically rewritable semiconductor memory device according to claim 1,
wherein the rewrite status is acquired by monitoring a data storage property of the nonvolatile semiconductor memory.

5. The electrically rewritable semiconductor memory device according to claim 4, further comprising:
an electrically rewritable nonvolatile semiconductor memory for referring to the number of rewrite operations in an additional region,
wherein the electrically rewritable nonvolatile semiconductor memory for referring to the number of rewrite operations is rewritten while a data region is rewritten.

6. The electrically rewritable semiconductor memory device according to claim 4,
wherein the rewrite status is acquired by monitoring a data storage property of a nonvolatile semiconductor memory just before the data region is read.

7. The electrically rewritable semiconductor memory device according to claim 4,
wherein the rewrite status is acquired by monitoring a data storage property when a predetermined time is passed after a nonvolatile semiconductor memory is rewritten.

8. The electrically rewritable semiconductor memory device according to claim 4,
wherein the data storage property is acquired by monitoring the data storage properties with respect to both data “0” and data “1”.

9. The electrically rewritable semiconductor memory device according to claim 4,
wherein the data storage property is monitored with respect to one of data “0” and data “1” which has a data storage property stronger than the other.

10. The electrically rewritable semiconductor memory device according to claim 4,
wherein the data storage property is monitored with respect to one of data “0” and data “1” which has a data storage property no stronger than the other.

11. The electrically rewritable semiconductor memory device according to claim 2,
wherein a data storage property during test is reflected to the read condition.

12. The electrically rewritable semiconductor memory device according to claim 3,
wherein a rewrite property during a test is stored in a chip, and the difference of rewrite properties stored in the chip is reflected to the read condition when performing a rewrite operation in the nonvolatile semiconductor memory.

13. The electrically rewritable semiconductor memory device according to claim 1,
wherein the nonvolatile semiconductor memory is a flash memory.

14. The electrically rewritable semiconductor memory device according to claim 1,
wherein the nonvolatile semiconductor memory is a ferroelectric memory (FeRAM).
